(19) United States
(12) Patent Application Publication
(10) Pub. No.: US 2025/0246494 A1
(43) Pub. Date: Jul. 31, 2025

(54) SEMICONDUCTOR STRUCTURE AND MANUFACTURING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/623,391

(22) Filed: Apr. 1, 2024

(30) Foreign Application Priority Data
Jan. 29, 2024 (CN) 202410122544.9

(51) Int. Cl. H01L 23/31; H01L 23/29; H01L 29/66; H01L 29/778

(52) U.S. Cl. CPC H01L 23/3178; H01L 23/291; H10D 30/015; H10D 30/47

(57) ABSTRACT

A semiconductor structure includes a substrate, a channel layer, a barrier layer, and a passivation layer sequentially stacked; the passivation layer includes first and second passivation layers, the first passivation layer has a plurality of strip-shaped structures, a first groove is formed between any two adjacent strip-shaped structures, the second passivation layer at least covers the first groove, and an ability of the second passivation layer to consume a two-dimensional electron gas is greater than that of the first passivation layer to consume a two-dimensional electron gas. A concentration of a two-dimensional electron gas in the channel layer below the second passivation layer is modulated by using the high-concentration hydrogen ion in the second passivation layer, so that a decrease of a transconductance curve at a relatively large drain current is slowed down to improve a transconductance flatness of a device, improving a linearity of the device.

### CROSS-REFERENCE TO RELATED APPLICATIONS

The present disclosure claims priority to the Chinese Patent Application 202410122544.9, filed on Jan. 29, 2024, the content of which is incorporated herein by reference in its entirety.

### TECHNICAL FIELD

The present disclosure relates to the field of semiconductor technologies, and in particular, to a semiconductor structure and a manufacturing method thereof.

### BACKGROUND

Gallium nitride (GaN) materials have advantages of wide band gap, high breakdown field strength, and the like. An AlGaN/GaN heterojunction device based on gallium nitride has a relatively high electron mobility, and a high-concentration two-dimensional electron gas (2DEG) can be formed at a heterojunction interface through polarization in case of unintentional doping, so that a gallium nitride-based high-electron-mobility transistor (GaN HEMT) device has a broad application prospect in a field of microwave power. However, as for the GaN HEMT device, there is a serious nonlinear problem, which severely restricts applications of the GaN HEMT device in a field of communications.

### SUMMARY

In view of this, embodiments of the present disclosure provide a semiconductor structure and a manufacturing method thereof, so as to further improve a linearity of a gallium nitride-based high-electron-mobility transistor device.

According to a first aspect, embodiments of the present disclosure provide a semiconductor structure, which includes: a substrate, a channel layer, a barrier layer, and a passivation layer that are sequentially stacked; the passivation layer includes a first passivation layer and a second passivation layer, the first passivation layer has a plurality of strip-shaped structures, each of the plurality of strip-shaped structures extends in a first direction, a first groove is formed between any two adjacent strip-shaped structures in the plurality of strip-shaped structures, the second passivation layer at least covers the first groove, and an ability of the second passivation layer to consume a two-dimensional electron gas is greater than an ability of the first passivation layer to consume a two-dimensional electron gas.

As an alternative embodiment, a hydrogen concentration of the second passivation layer is greater than a hydrogen concentration of the first passivation layer.

As an alternative embodiment, a material of the second passivation layer includes at least one of SiN, SiO₂, Al₂O₃, HfO₂, HfZrO, or AlN.

As an alternative embodiment, a hydrogen concentration of the second passivation layer is greater than or equal to 1E18/cm³ and less than or equal to 1E22/cm³.

As an alternative embodiment, a material of the first passivation layer includes in-situ grown SiN.

As an alternative embodiment, the first groove and the first passivation layer are covered by the second passivation layer.

As an alternative embodiment, in a plane perpendicular to the first direction, a cross section shape of the first passivation layer includes at least one of a rectangle, a trapezoid, a triangle, or an arc.

As an alternative embodiment, at least two of the plurality of strip-shaped structures have different widths in a direction perpendicular to the first direction and perpendicular to a direction from the substrate to the barrier layer.

As an alternative embodiment, in a direction perpendicular to the first direction and perpendicular to a direction from the substrate to the barrier layer, at least two pairs of adjacent strip-shaped structures in the plurality of strip-shaped structures have different spacing distances.

As an alternative embodiment, the semiconductor structure further includes: a source electrode located on the barrier layer; a drain electrode located on the barrier layer, and a direction from the source electrode to the drain electrode being parallel to the first direction; and a gate electrode located on the passivation layer and located between the source electrode and the drain electrode.

According to another aspect, an embodiment of the present disclosure provides a method for manufacturing a semiconductor structure, which includes: providing a substrate, and sequentially growing a channel layer and a barrier layer on the substrate; growing a first passivation layer on the barrier layer, and partially etching off the first passivation layer until exposing the barrier layer to form a plurality of strip-shaped structures, each of the plurality of strip-shaped structures extending in a first direction, and a first groove being formed between any two adjacent strip-shaped structures in the plurality of strip-shaped structures; and at least growing a second passivation layer in the first groove, and an ability of the second passivation layer to consume a two-dimensional electron gas being greater than an ability of the first passivation layer to consume a two-dimensional electron gas.

As an alternative embodiment, a method for growing the first passivation layer is to perform in-situ growth in a metal organic chemical vapor deposition cavity.

As an alternative embodiment, a growth mode of the second passivation layer includes one of plasma enhanced chemical vapor deposition or atomic layer deposition.

As an alternative embodiment, the second passivation layer is conformally disposed in the first groove and on the first passivation layer.

As an alternative embodiment, the method for manufacturing the semiconductor structure further includes: etching off the passivation layer until exposing the barrier layer to form a source region and a drain region, providing a source electrode in the source region, providing a drain electrode in the drain region, and providing a gate electrode on the passivation layer, and a direction from the source electrode to the drain electrode being parallel to the first direction.

### BRIEF DESCRIPTION OF THE DRAWINGS

FIG. 1a is a schematic structural diagram of a semiconductor structure according to an embodiment of the present disclosure.

FIG. 1b is a schematic structural diagram of a cross-section AA′ of the semiconductor structure in FIG. 1a.

FIG. 2a is a schematic structural diagram of a semiconductor structure according to an embodiment of the present disclosure.

FIG. 2b is a schematic structural diagram of a cross-section AA′ of the semiconductor structure in FIG. 2a.

FIG. 3a to FIG. 3d are schematic side views of semiconductor structures according to some embodiments of the present disclosure.

FIG. 4 and FIG. 5 are schematic side views of semiconductor structures according to some embodiments of the present disclosure.

FIG. 6 is a flowchart of a method for manufacturing a semiconductor structure according to an embodiment of the present disclosure.

FIG. 7 to FIG. 11 are schematic structural diagrams of intermediate structures generated during a manufacturing process of a semiconductor structure according to an embodiment of the present disclosure.

### DETAILED DESCRIPTION OF THE EMBODIMENTS

Technical solutions in the embodiments of the present disclosure are clearly and completely described below with reference to the accompanying drawings in the embodiments of the present disclosure. Apparently, the described embodiments are a part of the embodiments of the present disclosure, rather than all the embodiments. All other embodiments obtained by a person of ordinary skill in the art based on the embodiments of the present disclosure without creative efforts shall fall within the protection scope of the present disclosure.

In order to further improve a linearity of a gallium nitride-based high-electron-mobility transistor device, the present disclosure provides a semiconductor structure and a manufacturing method thereof, and the semiconductor structure includes a substrate, a channel layer, a barrier layer, and a passivation layer that are sequentially stacked; the passivation layer includes a first passivation layer and a second passivation layer, the first passivation layer has a plurality of strip-shaped structures, each of the plurality of strip-shaped structures extends in a first direction, a first groove is formed between any two adjacent strip-shaped structures, the second passivation layer at least covers the first groove, and an ability of the second passivation layer to consume a two-dimensional electron gas is greater than an ability of the first passivation layer to consume a two-dimensional electron gas. The second passivation layer of the present disclosure has high-concentration hydrogen ion, and a concentration of a two-dimensional electron gas in the channel layer below the second passivation layer may be modulated by using the high-concentration hydrogen ion in the second passivation layer, so that on one hand, different threshold voltages may be formed in the channel layers below the first passivation layer and the second passivation layer to improve a withstand voltage, and on the other hand, a decrease of a transconductance curve at a relatively large drain current may be slowed down to improve a transconductance flatness of a device, improving a linearity of the device. In addition, impurities cannot adsorb or introduce into the first passivation layer grown in-situ, reducing an interface state density of the first passivation layer, and further facilitating to reduce a current collapse effect in a device and reduce a leakage current.

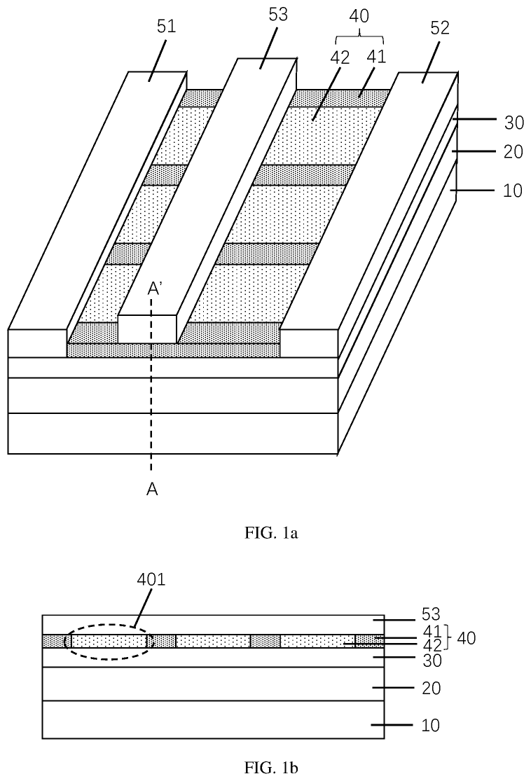

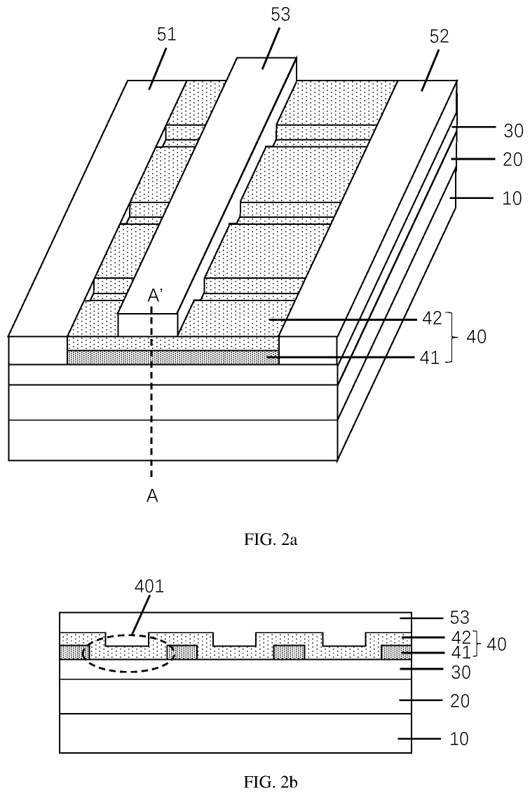

A semiconductor structure and a manufacturing method thereof mentioned in the present disclosure are further illustrated below with reference to FIG. 1a to FIG. 11.

FIG. 1a is a schematic structural diagram of a semiconductor structure according to an embodiment of the present disclosure. FIG. 1b is a schematic structural diagram of a cross-section AA′ of the semiconductor structure in FIG. 1a. As shown in FIG. 1a, the semiconductor structure includes a substrate 10, a channel layer 20, a barrier layer 30, and a passivation layer 40 that are sequentially stacked; the passivation layer 40 includes a first passivation layer 41 and a second passivation layer 42, the first passivation layer 41 has a plurality of strip-shaped structures, each of the plurality of strip-shaped structures extends in a first direction, a first groove 401 is formed between any two adjacent strip-shaped structures, the second passivation layer 42 at least covers the first groove 401 (shown in FIG. 1b), and an ability of the second passivation layer 42 to consume a two-dimensional electron gas is greater than an ability of the first passivation layer 41 to consume a two-dimensional electron gas. As shown in FIG. 1a, the semiconductor structure further includes: a source electrode 51 located on the barrier layer 30; a drain electrode 52 located on the barrier layer 30, and a direction from the source electrode 51 to the drain electrode 52 being parallel to the first direction; and a gate electrode 53 located on the passivation layer 40 and located between the source electrode 51 and the drain electrode 52.

In this embodiment, a material of the substrate 10 may include sapphire, silicon carbide, silicon, GaN, or diamond. Materials of the channel layer 20 and the barrier layer 30 may include Group III nitride, and a two-dimensional electron gas may be formed at an interface between the channel layer 20 and the barrier layer 30. In an optional solution, the channel layer 20 is a GaN layer, and the barrier layer 30 is an AlGaN layer. In other optional solutions, a material combination of the channel layer 20 and the barrier layer 30 may also include GaN/AlN, GaN/InN, GaN/InAlGaN, GaN/InAlN or InN/InAlN.

In this embodiment, the abilities of the first passivation layer 41 and the second passivation layer 42 to consume the two-dimensional electron gas are reflected by a hydrogen concentration, a hydrogen concentration of the second passivation layer 42 is greater than a hydrogen concentration of the first passivation layer 41, and the larger the hydrogen concentration of the second passivation layer 42, the greater the ability of the second passivation layer 42 to consume the two-dimensional electron gas in the channel layer 20. A material of the second passivation layer 42 includes at least one of SiN, SiO₂, Al₂O₃, HfO₂, HfZrO, or AIN grown by Plasma Enhanced Chemical Vapor Deposition (PECVD) or Atomic Layer Deposition (ALD). A hydrogen ion concentration of the second passivation layer 42 is greater than or equal to 1E18/cm³ and less than or equal to 1E22/cm³. A material of the first passivation layer 41 includes in-situ grown SiN, and a hydrogen ion concentration of the in-situ grown SiN is relatively low, and is lower than a hydrogen ion concentration of materials such as SiN grown by PECVD, ALD, or the like. The second passivation layer 42 has high-concentration hydrogen ion, a concentration of a two-dimensional electron gas at an interface between the channel layer 20 and the barrier layer 30 below the second passivation layer 42 may be modulated by using the high-concentration hydrogen ion in the second passivation layer 42, and the first passivation layer 41 has a strip-shaped structure distributed at intervals along a channel width direction (i.e., a direction perpendicular to the first direction and perpendicular to a direction from the substrate 10 to the barrier layer 30), and therefore, on one hand, different threshold voltages may be formed at different positions of the channel layer 20 to improve a withstand voltage, and on the other hand, a decrease of a transconductance curve at a relatively large drain current may be slowed down to improve a transconductance flatness of a device, improving a linearity of the device. Optionally, materials of the first passivation layer 41 and the second passivation layer 42 are different, which may form a plurality of different Metal-Insulator-Semiconductor (MIS) gate devices, and different MIS gate devices may be connected in parallel, implementing multi-threshold coupling of devices, and further improving a linearity of a device.

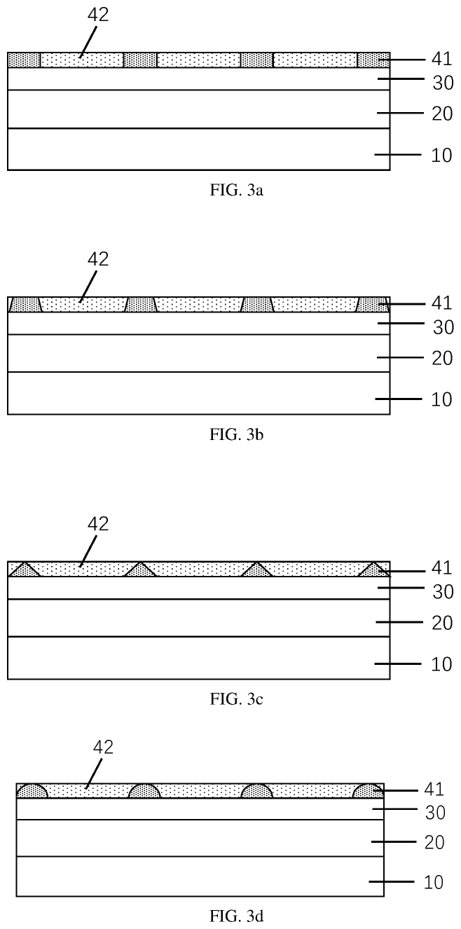

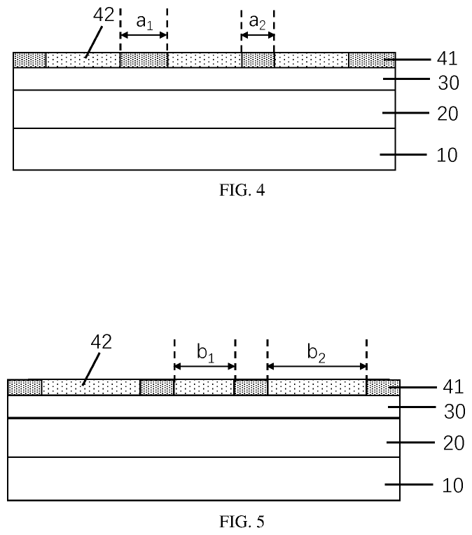

FIG. 2a is a schematic structural diagram of a semiconductor structure according to an embodiment of the present disclosure. FIG. 2b is a schematic structural diagram of a cross-section AA′ of the semiconductor structure in FIG. 2a. In an embodiment, as shown in FIG. 1b, the second passivation layer 42 only covers the first groove 401. In another embodiment, as shown in FIG. 2a and FIG. 2b, the second passivation layer 42 not only covers the first groove 401, but also covers the first passivation layer 41, the second passivation layer 42 is conformally disposed in the first groove 401 and on the first passivation layer 41, the second passivation layer 42 has a groove corresponding to the first groove 401, and the groove in the second passivation layer 42 is filled by the gate electrode 53, i.e., a surface, close to a substrate 10, of the gate electrode 53 is not on a same plane. Since the surface, close to the substrate 10, of the gate electrode 53 is not on a same plane, a distance between the gate electrode 53 and the channel layer 20 changes in the direction perpendicular to the first direction and perpendicular to the direction from the substrate 10 to the barrier layer 30, so that abilities at different positions of the gate electrode 53 to control a two-dimensional electron gas are different (this is equivalent to a plurality of devices connected in parallel), further improving a linearity of a device.

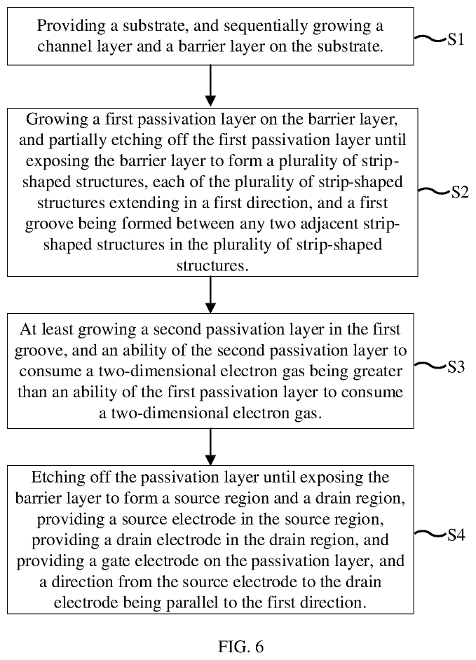

FIG. 3a to FIG. 3d are schematic side views of semiconductor structures according to some embodiments of the present disclosure. In an embodiment, in a plane perpendicular to the first direction, a cross section shape of the first passivation layer 41 includes at least one of a rectangle (shown in FIG. 3a), a trapezoid (shown in FIG. 3b), a triangle (shown in FIG. 3c), or an arc (shown in FIG. 3d). The cross section shape of the first passivation layer 41 is not specifically limited in the present disclosure. Changing the cross section shape of the first passivation layer 41 may change a distance between a side surface of the first passivation layer 41 and the channel layer 20, and may change a projection area of the first passivation layer 41 on a plane where the channel layer 20 is located, so that a distance between a side surface of the second passivation layer 42 and the channel layer 20 may be changed, and a projection area of the second passivation layer 42 on the plane where the channel layer 20 is located may be changed, further modulating a two-dimensional electron gas, and further improving a linearity of a semiconductor structure.

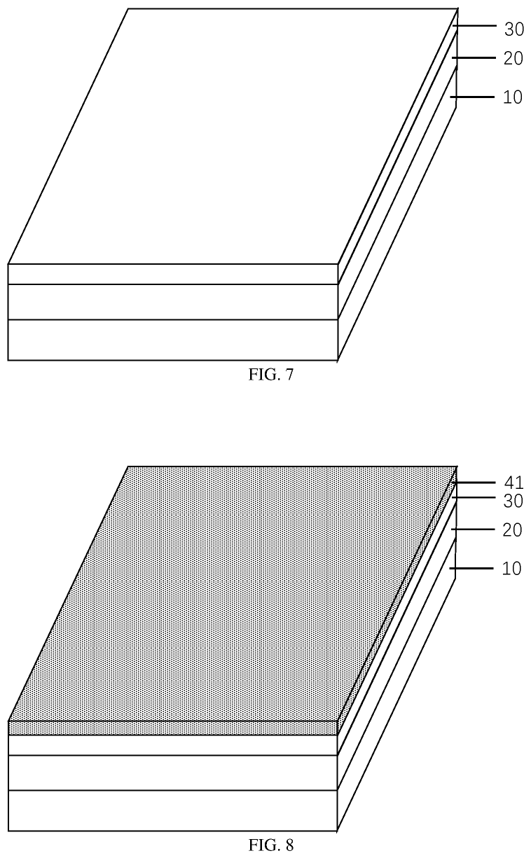

FIG. 4 and FIG. 5 are schematic side views of semiconductor structures according to some embodiments of the present disclosure. In an embodiment, as shown in FIG. 4, at least two of the plurality of strip-shaped structures have different widths (a₁, a₂) in the direction perpendicular to the first direction and perpendicular to the direction from the substrate 10 to the barrier layer 30. In another embodiment, as shown in FIG. 5, in the direction perpendicular to the first direction and perpendicular to the direction from the substrate 10 to the barrier layer 30, at least two pairs of adjacent strip-shaped structures in the plurality of strip-shaped structures have different spacing distances (b₁, b₂). The width of the strip-shaped structure or the spacing distance between adjacent strip-shaped structures is changed, so that on one hand, a transconductance peak value at different positions of the channel layer 20 may be changed, and on the other hand, a threshold voltage at different positions of the channel layer 20 may be changed to improve a withstand voltage, improving linear working characteristics of a device.

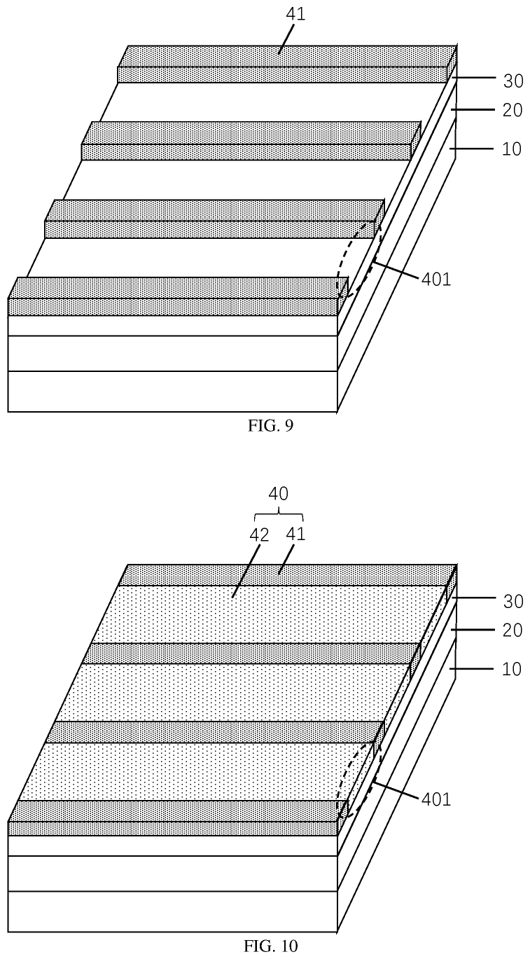

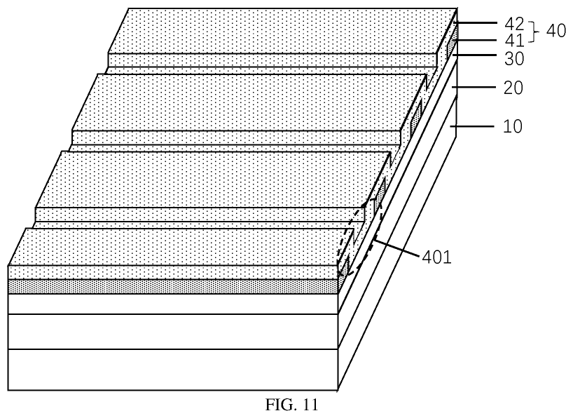

According to another aspect of the present disclosure, FIG. 6 is a flowchart of a method for manufacturing a semiconductor structure according to an embodiment of the present disclosure, and FIG. 7 to FIG. 11 are schematic structural diagrams of intermediate structures generated during a manufacturing process of a semiconductor structure according to an embodiment of the present disclosure. As shown in FIG. 6, a method for manufacturing a semiconductor structure according to an embodiment of the present disclosure includes the following steps.

Step S1: providing a substrate, and sequentially growing a channel layer and a barrier layer on the substrate.

As shown in FIG. 7, the substrate 10 is provided, and the channel layer 20 and the barrier layer 30 are sequentially grown on the substrate 10. A material of the substrate 10 may include sapphire, silicon carbide, silicon, GaN or diamond. The channel layer 20 and the barrier layer 30 may be grown in-situ, and the channel layer 20 and the barrier layer 30 may also be prepared by Atomic Layer Deposition (ALD), Chemical Vapor Deposition (CVD), Molecular Beam Epitaxy (MBE), Plasma Enhanced Chemical Vapor Deposition (PECVD), Low Pressure Chemical Vapor Deposition (LPCVD), Metal-Organic Chemical Vapor Deposition (MOCVD), or a combination thereof.

Step S2: growing a first passivation layer on the barrier layer, and partially etching off the first passivation layer until exposing the barrier layer to form a plurality of strip-shaped structures, each of the plurality of strip-shaped structures extending in a first direction, and a first groove being formed between any two adjacent strip-shaped structures in the plurality of strip-shaped structures.

As shown in FIG. 8, the first passivation layer 41 is grown on the barrier layer 30, and as shown in FIG. 9, the first passivation layer 41 is partially etched off until the barrier layer 30 is exposed to form the plurality of strip-shaped structures, each strip-shaped structure extends in the first direction, and the first groove 401 is formed between any two adjacent strip-shaped structures. A material of the first passivation layer 41 includes SiN. A method for growing the first passivation layer 41 is to perform in-situ growth in a MOCVD cavity, a hydrogen ion concentration of an in-situ grown SiN is relatively low, and is lower than a hydrogen ion concentration of materials such as SiN grown by PECVD, ALD, or the like. Compared with a passivation layer material that is not grown in-situ, impurities cannot adsorb or introduce into an passivation layer material that is grown in-situ, so that a relatively small interface state density of the first passivation layer may be maintained, and in addition, a passivation effect of the passivation layer material that is grown in-situ is better, which is beneficial for reducing a current collapse effect in a device and reducing a leakage current.

Step S3: at least growing a second passivation layer in the first groove, and an ability of the second passivation layer to consume a two-dimensional electron gas being greater than an ability of the first passivation layer to consume a two-dimensional electron gas.

As shown in FIG. 10, only the second passivation layer 42 is grown in the first groove 401, a growth mode of the second passivation layer 42 includes one of PECVD or ALD, and the second passivation layer 42 has high-concentration hydrogen ion. A concentration of a two-dimensional electron gas at an interface between the channel layer 20 and the barrier layer 30 below the second passivation layer 42 may be modulated by using the high-concentration hydrogen ion in the second passivation layer 42. The second passivation layer 42 and the first passivation layer 41 are alternately arranged to form a plurality of different MIS gate devices, and the different MIS gate devices are connected in parallel, implementing multi-threshold coupling of devices, and further improving a linearity of a device.

In an embodiment, as shown in FIG. 11, the second passivation layer 42 is conformally disposed in the first groove 401 and on the first passivation layer 41. The second passivation layer 42 has a groove corresponding to the first groove 401, and the groove in the second passivation layer 42 is filled by the gate electrode 53, i.e., a surface, close to a substrate 10, of the gate electrode 53 is not on a same plane. Since the surface, close to the substrate 10, of the gate electrode 53 is not on a same plane, a distance between the gate electrode 53 and the channel layer 20 changes in a direction perpendicular to the first direction and perpendicular to a direction from the substrate 10 to the barrier layer 30, so that abilities at different positions of the gate electrode 53 to control a two-dimensional electron gas are different (this is equivalent to a plurality of devices connected in parallel), further improving a linearity of a device.

Step S4: etching off the passivation layer until exposing the barrier layer to form a source region and a drain region, providing a source electrode in the source region, providing a drain electrode in the drain region, and providing a gate electrode on the passivation layer, and a direction from the source electrode to the drain electrode being parallel to the first direction.

The passivation layer 40 is etched off until the barrier layer 30 is exposed to form the source region and the drain region, the source electrode 51 is disposed in the source region, the drain electrode 52 is disposed in the drain region, the gate electrode 53 is disposed on the passivation layer 40, and the direction from the source electrode 51 to the drain electrode 52 is parallel to the first direction, so that the semiconductor structure is formed shown in FIG. 1a.

The present disclosure provides a semiconductor structure and a manufacturing method thereof. The semiconductor structure includes a substrate, a channel layer, a barrier layer, and a passivation layer that are sequentially stacked; the passivation layer includes a first passivation layer and a second passivation layer, the first passivation layer has a plurality of strip-shaped structures, each of the plurality of strip-shaped structures extends in a first direction, a first groove is formed between any two adjacent strip-shaped structures, the second passivation layer at least covers the first groove, and an ability of the second passivation layer to consume a two-dimensional electron gas is greater than an ability of the first passivation layer to consume a two-dimensional electron gas. The second passivation layer of the present disclosure has high-concentration hydrogen ion, and a concentration of a two-dimensional electron gas in the channel layer below the second passivation layer may be modulated by using the high-concentration hydrogen ion in the second passivation layer, so that on one hand, different threshold voltages may be formed in the channel layers below the first passivation layer and the second passivation layer to improve a withstand voltage, and on the other hand, a decrease of a transconductance curve at a relatively large drain current may be slowed down to improve a transconductance flatness of a device, improving a linearity of the device. In addition, impurities cannot adsorb or introduce into the first passivation layer grown in-situ, reducing an interface state density of the first passivation layer, and further facilitating to reduce a current collapse effect in a device and reduce a leakage current.

It should be understood that the terms “including” and variations thereof used in the present disclosure are open-ended inclusion, i.e., “including but not limited to”. The term “an embodiment” means “at least one embodiment”; the term “another embodiment” means “at least one further embodiment”. In this specification, schematic representations of the above terms do not necessarily refer to the same embodiment or example. Furthermore, the particular features, structures, materials, or characteristics may be combined in any suitable manner in any one or more embodiments or examples. In addition, different embodiments or examples and features in different embodiments or examples described in this specification may be combined and bond by a person of ordinary skill in the art without contradicting each other.

The above are only preferred embodiments of the present disclosure and are not intended to limit the present disclosure, and any modification, equivalent replacement, and the like made within the spirit and principle of the present disclosure shall fall within the protection scope of the present disclosure.

What is claimed is:

1. A semiconductor structure, comprising:
a substrate, a channel layer, a barrier layer, and a passivation layer that are sequentially stacked;
wherein the passivation layer comprises a first passivation layer and a second passivation layer, the first passivation layer has a plurality of strip-shaped structures, each of the plurality of strip-shaped structures extends in a first direction, a first groove is formed between any two adjacent strip-shaped structures in the plurality of strip-shaped structures, the second passivation layer at least covers the first groove, and an ability of the second passivation layer to consume a two-dimensional electron gas is greater than an ability of the first passivation layer to consume a two-dimensional electron gas.

2. The semiconductor structure according to claim 1, wherein a hydrogen concentration of the second passivation layer is greater than a hydrogen concentration of the first passivation layer.

3. The semiconductor structure according to claim 1, wherein a material of the second passivation layer comprises at least one of SiN, SiO₂, Al₂O₃, HfO₂, HfZrO, or AlN.

4. The semiconductor structure according to claim 3, wherein a hydrogen concentration of the second passivation layer is greater than or equal to 1E18/cm³ and less than or equal to 1E22/cm³.

5. The semiconductor structure according to claim 1, wherein a material of the first passivation layer comprises in-situ grown SiN.

6. The semiconductor structure according to claim 1, wherein the first groove and the first passivation layer are covered by the second passivation layer.

7. The semiconductor structure according to claim 1, wherein in a plane perpendicular to the first direction, a cross section shape of the first passivation layer comprises at least one of a rectangle, a trapezoid, a triangle, or an arc.

8. The semiconductor structure according to claim 1, wherein at least two of the plurality of strip-shaped structures have different widths in a direction perpendicular to the first direction and perpendicular to a direction from the substrate to the barrier layer.

9. The semiconductor structure according to claim 1, wherein in a direction perpendicular to the first direction and perpendicular to a direction from the substrate to the barrier layer, at least two pairs of adjacent strip-shaped structures in the plurality of strip-shaped structures have different spacing distances.

10. The semiconductor structure according to claim 1, further comprising:
a source electrode located on the barrier layer;
a drain electrode located on the barrier layer, and a direction from the source electrode to the drain electrode being parallel to the first direction; and
a gate electrode located on the passivation layer and located between the source electrode and the drain electrode.

11. A method for manufacturing a semiconductor structure, comprising:
providing a substrate, and sequentially growing a channel layer and a barrier layer on the substrate;
growing a first passivation layer on the barrier layer, and partially etching off the first passivation layer until exposing the barrier layer to form a plurality of strip-shaped structures, each of the plurality of strip-shaped structures extending in a first direction, and a first groove being formed between any two adjacent strip-shaped structures in the plurality of strip-shaped structures; and
at least growing a second passivation layer in the first groove, and an ability of the second passivation layer to consume a two-dimensional electron gas being greater than an ability of the first passivation layer to consume a two-dimensional electron gas.

12. The method for manufacturing the semiconductor structure according to claim 11, wherein a method for growing the first passivation layer is to perform in-situ growth in a metal organic chemical vapor deposition cavity.

13. The method for manufacturing the semiconductor structure according to claim 11, wherein a growth mode of the second passivation layer comprises one of plasma enhanced chemical vapor deposition or atomic layer deposition.

14. The method for manufacturing the semiconductor structure according to claim 11, wherein the second passivation layer is conformally disposed in the first groove and on the first passivation layer.

15. The method for manufacturing the semiconductor structure according to claim 11, further comprising:
etching off the passivation layer until exposing the barrier layer to form a source region and a drain region, providing a source electrode in the source region, providing a drain electrode in the drain region, and providing a gate electrode on the passivation layer, and a direction from the source electrode to the drain electrode being parallel to the first direction.
